(19) United States
(12) Patent Application Publication
(10) Pub. No.: US 2013/0241627 A1
(43) Pub. Date: Sep. 19, 2013

(54) POWER SWITCH CIRCUIT

(71) Applicants: FU-LI GAO, Shenzhen City (CN); HSING-SUANG KAO, Tu-Cheng (TW)

(72) Inventors: FU-LI GAO, Shenzhen City (CN); HSING-SUANG KAO, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/437,024

(22) Filed: Apr. 2, 2012

(30) Foreign Application Priority Data
Mar. 16, 2012 (CN) 201210069303.X

(51) Int. Cl. H03K 17/687

(52) U.S. Cl. 327/427

(57) ABSTRACT

A power switch circuit includes a pulse width modulation (PWM) control circuit having a first frequency control terminal and a second frequency control terminal for outputting predetermined frequency signals, a first switch circuit, a second switch circuit, a first resistor connected between the first frequency control terminal and the first switch circuit, a second resistor connected between the first frequency control terminal and the second switch circuit, a first filtering circuit having a third resistor and a first capacitor, and a second filtering circuit having a fourth resistor and a second capacitor. A first terminal of the first capacitor is connected to the first switch circuit and a second terminal of the first capacitor is grounded via the third resistor. A first terminal of the second capacitor is connected to the second switch circuit and a second terminal of the second capacitor is grounded via the fourth resistor.

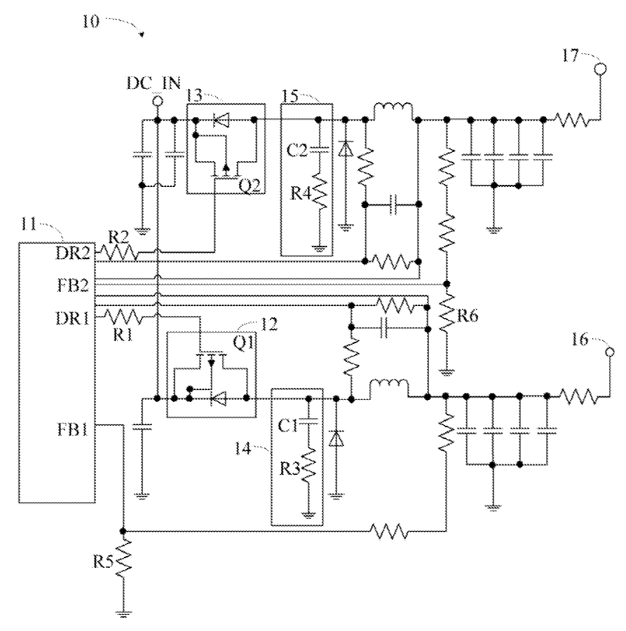

### BACKGROUND

1. Technical Field

The present disclosure relates to power switch circuits and, particularly, to a power switch circuit capable of reducing electromagnetic interference (EMI).

2. Description of the Related Art

EMI effects performance of electronic devices greatly. For example, when power is supplied to a power switch circuit in an electronic device, power system harmonics may be created at the moment that a switch element of the power switch circuit is turned on causing EMI.

### BRIEF DESCRIPTION OF THE DRAWING

The components in the drawing is not necessarily drawn to scale, the emphasis instead being placed upon clearly illustrating the principles of the disclosure. Moreover, in the drawing, like reference numerals designate corresponding parts throughout the several views.

The FIGURE is a circuit diagram of a power switch circuit in accordance with an exemplary embodiment.

### DETAILED DESCRIPTION

Referring to the FIGURE, a power switch circuit 10 includes a pulse-width modulation (PWM) control circuit 11, a first resistor R1, a second resistor R2, a first switch circuit 12, and a second switch circuit 13. The PWM control circuit 11 includes a first frequency control terminal DR1 and a second frequency control terminal DR2 configured for outputting predetermined frequency signals. A first terminal of the first resistor R1 is connected to the first frequency control terminal DR1, and a second terminal of the first resistor R1 is connected to the first switch circuit 12. A first terminal of the second resistor R2 is connected to the second frequency control terminal DR2, and a second terminal of the second resistor R2 is connected to the second switch circuit 13.

In the embodiment, the first switch circuit 12 includes a field effect transistor Q1, and the second switch circuit 13 includes a field effect transistor Q2. The second terminal of the first resistor R1 is connected to the grid of the field effect transistor Q1, the second terminal of the second resistor R2 is connected to the grid of the field effect transistor Q2. The drains of the field effect transistor Q1 and the field effect transistor Q2 are both connected to a power input port DC_IN.

The power switch circuit 10 further includes a first filtering circuit 14 and a second filtering circuit 15. The first filtering circuit 14 is connected between the first switch circuit 12 and a first output port 16 of the power switch circuit 10, and the second filtering circuit 15 is connected between the second switch circuit 13 and a second output port 17 of the power switch circuit 10. In the embodiment, the first filtering circuit 14 includes a third resistor R3 and a first capacitor C1. A first terminal of the first capacitor C1 is connected to the source of the field effect transistor Q1, and a second terminal of the first capacitor C1 is grounded via the third resistor R3. The second filtering circuit 15 includes a fourth resistor R4 and a second capacitor C2. A first terminal of the second capacitor C2 is connected to source of the field effect transistor Q2, and a second terminal of the second capacitor C2 is grounded via the fourth resistor R4.

In the embodiment, the PWM control circuit 11 is an integration circuit, and further includes a first feedback port FB1 grounded via a resistor R5 and a second feedback port FB2 grounded via a resistor R6. The first frequency control terminal DR1 is connected to the grid of the field effect transistor Q1, and the second frequency control terminal DR2 is connected to the grid of the field effect transistor Q2.

When the first frequency control terminal DR1 and the second frequency control terminal DR2 respectively output higher harmonics generated by the PWM control circuit 11, the first filtering circuit 14 and the second filtering circuit 15 are capable of restricting amplitude of the higher harmonics, thereby reducing electromagnetic interference of the power switch circuit 10.

In the embodiment, the power switch circuit 10 further includes other elements which are not related to the present disclosure and left out.

It is understood that the present disclosure may be embodied in other forms without departing from the spirit thereof. Thus, the present examples and embodiments are to be considered in all respects as illustrative and not restrictive, and the disclosure is not to be limited to the details given herein.

What is claimed is:

1. A power switch circuit, comprising:
a pulse width modulation (PWM) control circuit comprising a first frequency control terminal and a second frequency control terminal for outputting predetermined frequency signals;
a first switch circuit;
a second switch circuit;
a first resistor connected between the first frequency control terminal and the first switch circuit;
a second resistor connected between the first frequency control terminal and the second switch circuit;
a first filtering circuit comprising a third resistor and a first capacitor, wherein a first terminal of the first capacitor is connected to the first switch circuit and a second terminal of the first capacitor is grounded via the third resistor; and
a second filtering circuit comprising a fourth resistor and a second capacitor, wherein a first terminal of the second capacitor is connected to the second switch circuit and a second terminal of the second capacitor is grounded via the fourth resistor.

2. The power switch circuit as claimed in claim 1, wherein the first switch circuit comprises a first field effect transistor, and the second switch circuit comprises a second field effect transistor.

3. The power switch circuit as claimed in claim 2, wherein the second terminal of the first resistor is connected to the grid of the first field effect transistor, and the second terminal of the second resistor is connected to the grid of the second field effect transistor.

4. The power switch circuit as claimed in claim 2, wherein the first terminal of the first capacitor is connected to the source of the first field effect transistor, and the first terminal of the second capacitor is connected to the source of the second field effect transistor.
